(19) United States
(12) Patent Application Publication
(10) Pub. No.: US 2023/0231063 A1
(43) Pub. Date: Jul. 20, 2023

(54) OPTOELECTRONIC APPARATUS AND FABRICATION METHOD OF THE SAME

(71) Applicant: FUNDACIÓ INSTITUT DE CIÈNCIES FOTÒNIQUES, Castelldefels (ES)

(72) Inventors: Gerasimos Konstantatos, Castelldefels (ES); Frank Koppens, Castelldefels (ES); Dominik Kufer, Castelldefels (ES); Ivan Nikitskiy, Castelldefels (ES)

(73) Assignee: FUNDACIÓ INSTITUT DE CIÈNCIES FOTÒNIQUES, Castelldefels (ES)

(21) Appl. No.: 17/986,548

(22) Filed: Nov. 14, 2022

Related U.S. Application Data
(63) Continuation-in-part of application No. 14/800,320, filed on Jul. 15, 2015, now Pat. No. 11,527,662.

(30) Foreign Application Priority Data
Jul. 15, 2014 (EP) 14177172.5

(51) Int. Cl. H01L 31/0352; H01L 31/0224; H01L 31/0392

(52) U.S. Cl. CPC H01L 31/035218; H01L 31/022408; H01L 31/0392

(57) ABSTRACT

An optoelectronic apparatus, such as a photodetector apparatus comprising a substrate (1), a dielectric layer (2), a transport layer, and a photosensitizing layer (5). The transport layer comprises at least a 2-dimensional semiconductor 5 layer (3), and the photosensitizing layer (5) comprises colloidal quantum dots. Enhanced responsivity and extended spectral coverage are achieved with the disclosed structures.

### CROSS-REFERENCE TO RELATED APPLICATIONS

This is a continuation in part of U.S. patent application Ser. No. 14/800,320 filed Jul. 15, 2015, now U.S. Pat. No. 11,527,662.

### FIELD OF THE INVENTION

The present invention has its application within the optoelectronics sector and, especially, in the industrial area engaged in providing optoelectronic platforms with enhanced photoconductive gain.

### BACKGROUND OF THE INVENTION—RELATED ART

Many optoelectronic applications, such as photodetectors and photovoltaic cells, rely on the generation of an electric current under incidence of incoming light upon the device. Light absorption at an active layer triggers the separation of electron-hole pairs, with free electrons circulating through a transport layer driven by an electric field applied by electrodes. In order to provide an efficient conversion under diverse conditions and wavelength regimes, many optoelectronic platforms have been proposed over the years.

For example, WO 2013017605 A1 discloses an optoelectronic platform in which the transport layer consists of a semi-metallic carbon based conductor, such as graphene. A quantum dot sensitizing layer is also comprised in order to induce a change in the conductivity of the transport layer. In view of the high mobility of graphene and long lifetime of carriers in the quantum dots, a large photoconductive gain was achieved. However, this apparatus requires a high dark current level in order to achieve the desired responsivity. This dark current level requirement further affects the sensitivity and the shot-noise limit of the apparatus.

On the other hand, 2-dimensional semiconductors have also been used to implement transport layers in photoresponsive optoelectronic devices. For example, WO 2013063399 A1 presents an optoelectronic platform incorporating MoS2 layers. However, this technology presents a limited spectral coverage, determined by the bandgap of the MoS2.

Therefore, there is still the need in the state of the art of an optoelectronic platform, capable of providing a high responsivity for low dark current levels for a broad spectral range of incoming light.

### SUMMARY OF THE INVENTION

The current invention solves the aforementioned problems by disclosing an optoelectronic apparatus, and a method for its fabrication, which provide enhanced responsivity at low dark current levels and extended spectral coverage, due to the combination of a 2-dimensional semiconductor transport layer and a photosensitizing layer comprising colloidal quantum dots.

In a first aspect of the invention, an optoelectronic apparatus with enhanced responsivity and spectral coverage is disclosed. The optoelectronic apparatus comprises, from top to bottom, a photosensitizing layer, a transport layer, a dielectric layer and a substrate. Preferably, the optoelectronic apparatus is adapted to act as a photodetector by comprising a first electrode and a second electrode connected to the transport layer through two contacts of a conductor layer. Upon reception of incident light at the photosensitizing layer, an electric current between the first electrode and the second electrode is hence created through the transport layer. More preferably, the substrate is connected to a third electrode, therefore enabling to tune the conductivity of the transport by applying a bias voltage to said third electrode.

The photosensitizing layer comprises colloidal quantum dots for light absorption and transport layer conductivity modulation. Preferably, the photosensitizing layer comprise one or more of the following types of quantum dots: PbS, CIS (Copper indium disulfide), Ge, Si, HgTe, CIGS (Copper indium gallium selenide), CZTS (Copper zinc tin sulfide), AgBiS₂, SnO2, ITO (indium tin oxide) and ZnO.

The transport layer comprises at least a 2-dimensional semiconductor layer, being the number of 2-dimensional semiconductor layers preferably comprised between two and ten. Preferably, the 2-dimensional semiconductor layer (or layers) comprises one or more of the following materials: MoS₂, MoSe₂, WS₂, WSe₂, black phosphorous and SnS₂.

For an implementation of the first aspect of the invention, the optoelectronic apparatus comprises: a substrate, a dielectric layer, a transport layer, and a photosensitizing layer, wherein:
the transport layer comprises at least one 2-dimensional semiconductor layer, wherein the material of the 2-dimensional semiconductor layer is MoS₂;
the photosensitizing layer comprises colloidal quantum dots for absorbing light that, in response to incident light, generates pairs of electric carriers, traps a single type of electric carriers of said pairs therein, and transfers a distinct single type of electric carriers of said pairs to the transport layer, to be transported thereby,
   wherein the material of said colloidal quantum dots is selected from the group consisting of Ge, HgTe, and AgBiSe₂; and
wherein the optoelectronic apparatus further comprises:
   a first electrode and a second electrode connected to the transport layer, the transport layer being adapted to generate, and make flow through a transport channel, an electric current between the first electrode and the second electrode upon incidence of incoming light in the photosensitizing layer;
and further wherein a type-II heterojunction is formed between the photosensitizing layer and the transport layer to thereby provide a photoconductive gain.

For another implementation of the first aspect of the invention, the optoelectronic apparatus comprises: a substrate, a dielectric layer, a transport layer, and a photosensitizing layer, wherein:
the transport layer comprises at least one 2-dimensional semiconductor layer, wherein the material of the 2-dimensional semiconductor layer is selected from the group consisting of MoSe₂, WS₂, WSe₂, and SnS₂;
the photosensitizing layer comprises colloidal quantum dots for absorbing light that, in response to incident light, generates pairs of electric carriers, traps a single type of electric carriers of said pairs therein, and transfers a distinct single type of electric carriers of said pairs to the transport layer, to be transported thereby, wherein the material of said colloidal quantum dots is selected from the group consisting of Ge, HgTe, and AgBiSe₂; and
wherein the optoelectronic apparatus further comprises:
   a first electrode and a second electrode connected to the transport layer, the transport layer being adapted to generate, and make flow through a transport channel, an electric current between the first electrode and the second electrode upon incidence of incoming light in the photosensitizing layer;
and further wherein a type-II heterojunction is formed between the photosensitizing layer and the transport layer to thereby provide a photoconductive gain.

For still another implementation of the first aspect of the invention, the optoelectronic apparatus comprises: a substrate, a dielectric layer, a transport layer, and a photosensitizing layer, wherein:
the transport layer comprises at least one 2-dimensional semiconductor layer, wherein the material of the 2-dimensional semiconductor layer is selected from the group consisting of MoSe₂, WS₂, WSe₂, and SnS₂;
the photosensitizing layer comprises colloidal quantum dots for absorbing light that, in response to incident light, generates pairs of electric carriers, traps a single type of electric carriers of said pairs therein, and transfers a distinct single type of electric carriers of said pairs to the transport layer, to be transported thereby, wherein the material of said colloidal quantum dots is PbS; and
wherein the optoelectronic apparatus further comprises:
   a first electrode and a second electrode connected to the transport layer, the transport layer being adapted to generate, and make flow through a transport channel, an electric current between the first electrode and the second electrode upon incidence of incoming light in the photosensitizing layer;
and further wherein a type-II heterojunction is formed between the photosensitizing layer and the transport layer to thereby provide a photoconductive gain. A type-II heterojunction occurs when:
   1. The bandgap (E_{g,2DS}) of the transport layer, in this case a 2D semiconductor (2DS), is larger than the bandgap (E_{g,qd}) of the photosensitizing layer, i.e., of the quantum dot layer, and
   2. Those bandgaps are aligned, as illustrated below, so that only one type of photogenerated carriers (electrons or holes) is injected from the photosensitizing layer to the transport layer.

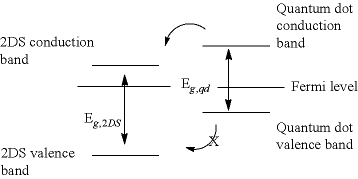

At least all the materials listed for the 2-dimensional semiconductor layer for the implementations described above, i.e., MoS2, MoSe2, WS2, WSe2, and SnS2, have a band gap of >1 eV in their two-dimensional form, i.e., in the form they are included in the optoelectronic apparatus of the invention, while also, at least all the materials listed for the colloidal quantum dots of the photosensitizing layer for the implementations described above, i.e., Ge, HgTe, AgBiSe2, and PbS have a bandgap <1 eV.

Therefore, for at least those implementations, the above indicated condition 1 for forming a type-II heterojunction is met, as all the materials for the transport layer have a band gap >1 eV and all the materials for the photosensitizing layer have a band gap <1 eV.

The above indicated condition 2 is indeed also met by all the implementations described above, as indeed the bandgaps are aligned as illustrated above, so that only one type of photogenerated carriers (electrons or holes) is injected from the photosensitizing layer to the transport layer. This can be achieved by several known processes, such as by ligand engineering of the colloidal quantum dot materials in the photosensitizing layer as is done in the following reference: “Energy Level Modification in Lead Sulfide Quantum Dot Thin Films through Ligand Exchange”; Patrick R. Brown et al. American Chemical Society, 2014.

The optoelectronic apparatus described by the invention is indeed providing photoconductive gain for all its implementations and embodiments. The type II heterojunction enables trapping of a single type of electrical carrier in the photosensitizing layer (for a duration t_{lifetime}) and transferring a distinct type of electrical carrier to the 2D semiconductor transport layer. When a bias is applied over the transport layer, the transit time tₜᵣₐₙₛᵢₜ of that current will provide a photoconductive gain given by the ratio t_{lifetime}/tₜᵣₐₙₛᵢₜ, i.e., a photoconductive gain will be provided.

The substrate layer preferably comprises a doped semiconductor selected between Si, ITO, AZO (Aluminum doped zinc oxide) and graphene. The dielectric layer preferably comprises at least one of the following materials: SiO₂, AlO₂, HfO₂, parylene and boron nitride.

For an embodiment, the optoelectronic apparatus further comprises a top electrode on top of the photosensitizing layer or on top of a dielectric layer arranged on top of the photosensitizing layer.

In some preferred embodiments, the optoelectronic apparatus further comprises an interlayer barrier located between the transport layer and the photosensitizing layer. Preferably, the interlayer barrier comprises either one of the following materials: ZnO, TiO₂, SiO₂, AlO₂, HfO₂ and boron nitride; or a self-assembled monolayer of organic molecules such as ethanedithiol, propanedithiol, butanedithiol, octanedithiol and dodecanedithiol. The thickness of the interlayer barrier is preferably comprised between 0.1 and 10 nm. Preferably, the interlayer barrier forms a type-II heterojunction with the photosensitizing layer, and a type-II or type-I heterojunction with the transport layer.

For an embodiment, the optoelectronic apparatus further comprises a third electrode connected to the substrate; and a voltage source connected to the third electrode and providing a bias voltage thereto to tune a conductivity of the transport layer by applying the bias voltage to the third electrode, to the point that the transport channel is depleted of free carriers in order to minimize its conductivity in dark.

For a variant of the above mentioned embodiment, the bias voltage provided by the voltage source ranges from 0.1 V to 10 V or from −0.1 to −10V. This variant corresponds to a practical implementation of the apparatus, where the dielectric layer will be thin and thus a large voltage is not necessary. Moreover, in a CMOS implementation, the max voltage sustained by the CMOS will be 10V. Hence, for this variant, the bias voltage is limited as indicated above. Depending on the polarity of the two-dimensional semiconductor, the gate voltage should be either positive or negative to be able to deplete the transport channel of free carriers.

In a second aspect of the present invention, a fabrication method of a photosensitive optoelectronic apparatus is disclosed. The method comprises depositing a dielectric layer, a transport layer and a photosensitizing layer on a substrate. The transport layer is deposited by depositing one or more 2-dimensional semiconductor layers. The photosensitizing layer comprises colloidal quantum dots. Preferably, the 2-dimensional semiconductor layers are either grown by chemical vapor deposition or exfoliated from a bulk crystal.

Note that all the preferred options of the apparatus of the invention (such as materials, structures, thicknesses, electrodes, etc.), can also be implemented as preferred options of the method of the invention by appropriately adapting any deposition and/or etching step thereof.

The disclosed apparatus and method provide an optoelectronic platform, which combines an enhanced responsivity under low dark current and an extended spectral range for photodetection. These and other advantages of the invention will become apparent from the following description and accompanying drawings.

### BRIEF DESCRIPTION OF THE DRAWINGS

For the purpose of aiding the understanding of the characteristics of the invention, according to a preferred practical embodiment thereof and in order to complement this description, the following figures are attached as an integral part thereof, having an illustrative and non-limiting character:

FIG. 1 shows a cross-sectional view of a preferred embodiment of the invention.

FIG. 2 is a scheme exemplifying the operation of said preferred embodiment as a photodetector.

FIG. 3 presents another embodiment of the invention, comprising an interlayer barrier between the transport layer and the quantum dot layer.

FIG. 4 compares the responsivity of an embodiment of the invention based on MoS₂ and a graphene/QD photodetector known in the state of the art.

FIG. 5 compares the responsivity of a MoS₂ photodetector with and without a quantum dots layer, according to a preferred embodiment of the invention.

FIG. 6 shows the spectral responsivity of a MoS₂-only phototransistor and of the equivalent hybrid MoS₂-Pbs detector.

FIG. 7 is a plot showing simulation results obtained with the optoelectronic apparatus of the present invention, for an embodiment for which the transport layer is made of MoS₂ and the material of the colloidal quantum dots is HgTe. The solid lines correspond to the conduction (upper) and valence (lower) bands, and the dashed line to the fermi level.

FIG. 8 is a plot showing simulation results obtained with the optoelectronic apparatus of the present invention, for an embodiment for which the transport layer is made of WS₂ and the material of the colloidal quantum dots is PbS. The solid lines correspond to the conduction (upper) and valence (lower) bands, and the dashed line to the fermi level.

FIG. 9 is a plot showing simulation results obtained with the optoelectronic apparatus of the present invention, for an embodiment for which the transport layer is made of MoS₂ and the material of the colloidal quantum dots is AgBiSe₂. The solid lines correspond to the conduction (upper) and valence (lower) bands, and the dashed line to the fermi level.

### DETAILED DESCRIPTION OF THE INVENTION

The matters defined in this detailed description are provided to assist in a comprehensive understanding of the invention. Accordingly, those of ordinary skill in the art will recognize that variation changes and modifications of the embodiments described herein can be made without departing from the scope and spirit of the invention. In particular, the preferred embodiments of the invention are described for an optoelectronic apparatus based on a MoS₂ transport layer sensitized with PbS quantum dots.

Nevertheless, the description of the photonic structures and of their underlying mechanism can be generally applied to other materials. Specifically, as indicated in a previous section, for each of MoS₂, MoSe₂, WS₂, WSe₂, and SnS₂, for the transport layer, combined with each of Ge, HgTe, AgBiSe2, and PbS, for the photosensitizing layer, in any possible combination, as indeed for all those combinations a type-II heterojunction is formed that enables trapping of a single type of electrical carrier (electrons or holes) in the photosensitizing layer and transferring a distinct type of electrical carrier (holes or electrons) to the 2D semiconductor transport layer, and thus photoconductive gain is provided.

Note that in this text, the term “comprises” and its derivations (such as “comprising”, etc.) should not be understood in an excluding sense, that is, these terms should not be interpreted as excluding the possibility that what is described and defined may include further elements, steps, etc.

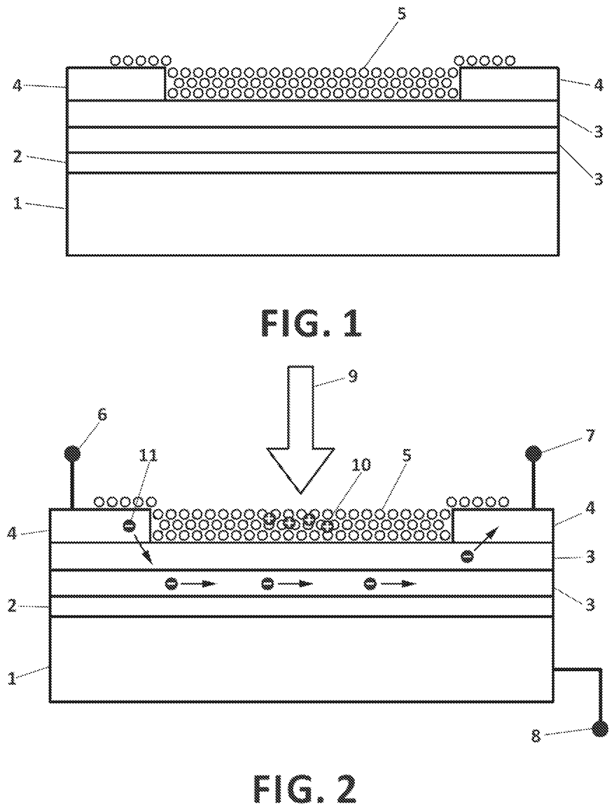

FIG. 1 shows a cross-sectional view of a preferred embodiment of the optoelectronic apparatus of the invention, fabricated according to a preferred embodiment of the method of the invention. The apparatus comprises a substrate 1 fabricated of a heavily doped semiconductor such as Silicon, on top of which is deposited a dielectric layer 2 of silicon oxide. The transport layer of the apparatus is implemented by two 2-dimensional semiconductor (2DS) layers 3 of any of the above mentioned materials (MoS₂, MoSe₂, WS₂, WSe₂, and SnS₂). The 2DS layers 3 are sensitized by a quantum dot (QD) sensitizing layer 5 made of any of the above mentioned materials (Ge, HgTe, AgBiSe2, and PbS). Alternatively, the transport layer can be implemented by less or more than two 2-dimensional semiconductor (2DS) layers 3.

For an embodiment, each 2DS layer 3 is a monolayer of MoS2 defined by three atomic layers (SMo-S), as opposed to single-atomic layer graphene. Moreover, MoS₂ possess a bandgap and therefore allows the operation of the device in the off state of the transport layer, determined by the application of a back gate voltage. This operation regime is not possible with graphene, due to the lack of the bandgap.

The 2DS layers 3 are sensitized by a PbS quantum dot (QD) sensitizing layer 5. Thus, the optical absorption of the apparatus and therefore its spectral sensitivity is determined by that of the QDs. The apparatus can hence detect photons that have lower energy than the bandgap of the transport layer, extending the spectral range for photodetection.

A conductor layer 4 partially covers the top 2DS layer 3, providing contact points for electrodes. The conductor layer 4 can be implemented, for example, with Ti, Au, or any other conductor with similar functionalities. The conduction layer 4 can be fabricated, for example, by selective deposition or by a complete deposition followed by a selective etching. Quantum dots are deposited in a two-step process involving treatment with 1,2-ethanedithiol (EDT) followed by PbS QD deposition. Initially the MoS2 layer becomes more n-type doped due to surface doping from EDT. The subsequent deposition of p-type PbS QDs turns the MoS₂ film again less n-type doped due to the formation of the heterojunction between the n-type MoS₂ transport layer and the p-type PbS QD sensitizing layer 5. The MoS₂ layer in its final configuration is still more n-type doped than the initial stand-alone flake, an effect that reduces the on/off-ratio in the experimental range of V_{G}.

Thicknesses of the layers of the apparatus preferably are selected from the following ranges:
Substrate layer 1: 0.1 nm-10 mm
Dielectric layer 2: 5 nm-400 nm
Transport layer: between 1 and 100 MoS₂ monolayers
QD layer 5: 2 nm-2,000 nm
Conductor layer 4: 0.1 nm-100,000 nm

Additional substrate layers 1 can be included to provide support to the whole apparatus, such as silicon substrates, glass substrates or flexible plastic substrates like polyethylene terephtalate (PET).

FIG. 2 presents an optoelectronic apparatus with the aforementioned structure and materials operating as a transistor. A first electrode 6 (drain electrode) and a second electrode 7 (source electrode) are connected to the top 2DS layer 3 through the conductor layer 4. A third electrode 8 (back-gate electrode) is connected to the substrate layer 1. Incident light 9 is absorbed by the QD layer 5, resulting in the separation of photoexcited electron 11—hole 10 pairs at the p-n-interface between MoS₂ and PbS, or between any of MoS₂, MoSe₂, WS₂, WSe₂, and SnS₂ and any of Ge, HgTe, AgBiSe2, and PbS. While holes 10 remain within the QD layer 5, electrons 11 circulate through the MoS₂ channel (or MoSe₂, WS₂, WSe₂ channel) driven by an electric field VDS applied between the drain electrode 6 and the source electrode 7. Alternatively, the opposite can also happen, i.e. electrons 11 remain within the QD layer 5 and holes 10 circulate through the transport channel. The current flow can be controlled electrically by applying an appropriate back-gate voltage (V_{G}) at the back-gate electrode 8. At strongly negative values of V_{G}, or at values of V_{G} ranging from 0.1 V to 10 V or from −0.1 to −10V (where the dielectric layer is thin and thus a large voltage is not necessary), the gating depletes the n-type MoS₂ sheet (or MoSe₂, WS₂, WSe₂ sheet), increasing the resistance of the device (operation in OFF mode). By increasing V_{G}, the MoS₂ channel (or MoSe₂, WS₂, WSe₂ channel) falls in the accumulation region and the transistor is in the ON state.

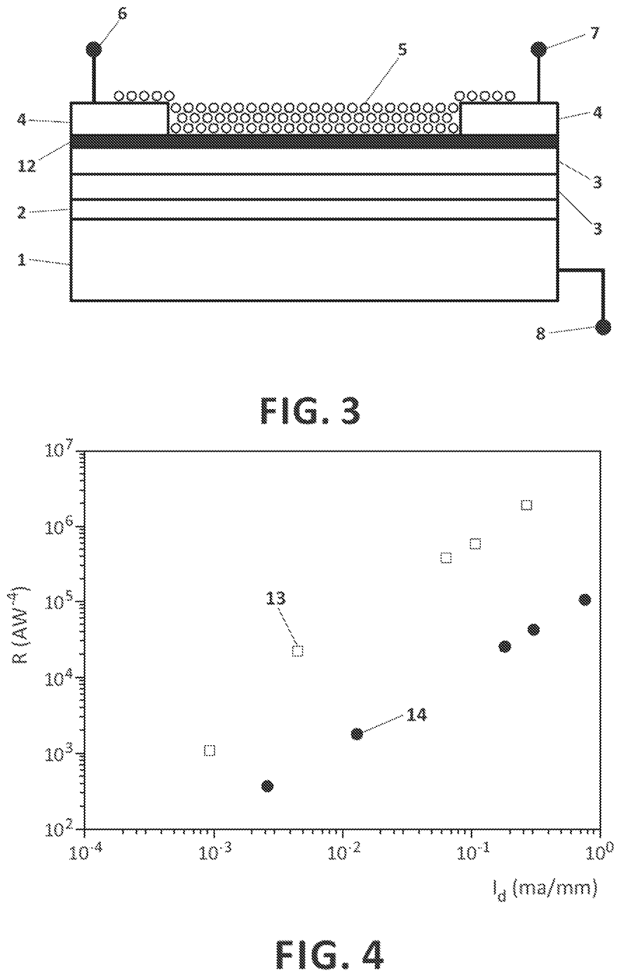

FIG. 3 shows a variation of the optoelectronic apparatus and method in which a thin interlayer barrier 12 is deposited between the top 2DS layer 3 and the QD layer 5. The interlayer barrier comprises ZnO, TiO₂, Alumina, Hafnia, boron nitride or a self-assembled monolayer of organic molecules including Ethane-, propane-, butane-, octane-or dodecane-dithiol molecules. The thickness of the interlayer barrier may vary from 0.1 nm up to 10 nm. The effect of the interlayer barrier is to tailor the electronic interface between the QD and 2DS layer to improve the performance of the device in achieving more efficient charge transfer, tailoring the temporal response and improve the stability of the device.

In all the optoelectronic apparatus, materials of the QD layer 5 and the transport layer are selected in order to ensure a high carrier mobility in the transport layer and hence a carrier transit time (tₜᵣₐₙₛᵢₜ) that is orders of magnitude shorter than the trapping lifetime (t_{lifetime}) in the quantum dots. Since the gain of the device is given by the ratio t_{lifetime}/tₜᵣₐₙₛᵢₜ, this selection of materials provides a highly responsive device. The temporal response of the hybrid photodetector is determined by t_{lifetime}, showing a time constant of ˜0.3 s for the particular case of a MoS₂/PbS device.

The existence of a bandgap in the channel of the transistor, which allows the facile tuning of the dark conductivity, is a powerful tool to increase the sensitivity of a detector implemented in the proposed optoelectronic platform, as the noise current in the shot noise limit scales as iₙ=(2qI_{d}B)^{1/2}, where q is the electron charge, I_{d} the dark current flowing in the device and B is the electrical bandwidth. The resultant sensitivity of the detector in the shot-noise limit is then expressed by the normalized detectivity as D*=R(AB)^{1/2}/iₙ where R is the responsivity, A the area of the device and B is the electrical bandwidth. At high negative back-gate bias, or at values of V_{G} ranging from 0.1 V to 10 V or from −0.1 to −10V, the channel is depleted from free carriers in the dark state and therefore the detector exhibits high sensitivity with D* reaching up to 7×10¹⁴ Jones at V_{G} of −100 V in the shot-noise limit. MoS₂/PbS photodetectors show significant performance even at very low applied electric field of 3.3 mV/pm with corresponding responsivity of 10 A/W. The presence of the bandgap in the MoS2 channel and thus the offered opportunity to tune the dark current via the back gate allows the achievement of similar responsivity values achieved via previously reported structures relying on graphene, albeit with lower dark current values. This reduction in the dark current is apparent in FIG. 4, which presents experimental results of the responsivity vs dark current for a MoS₂/PbS 13 and a graphene/QD 14 photodetectors. The MoS₂/PbS 13 photodetector can achieve the same responsivity with more than an order of magnitude reduction in the dark current. Similar results are obtained for photodetectors with a transport layer made of MoS₂, and a photosensitizing layer comprising colloidal quantum dots made of any of Ge, HgTe, and AgBiSe₂, and for photodetectors with a transport layer made of any of MoSe₂, WS₂, WSe₂, and a photosensitizing layer comprising colloidal quantum dots made of any of Ge, HgTe, AgBiSe₂, and PbS.

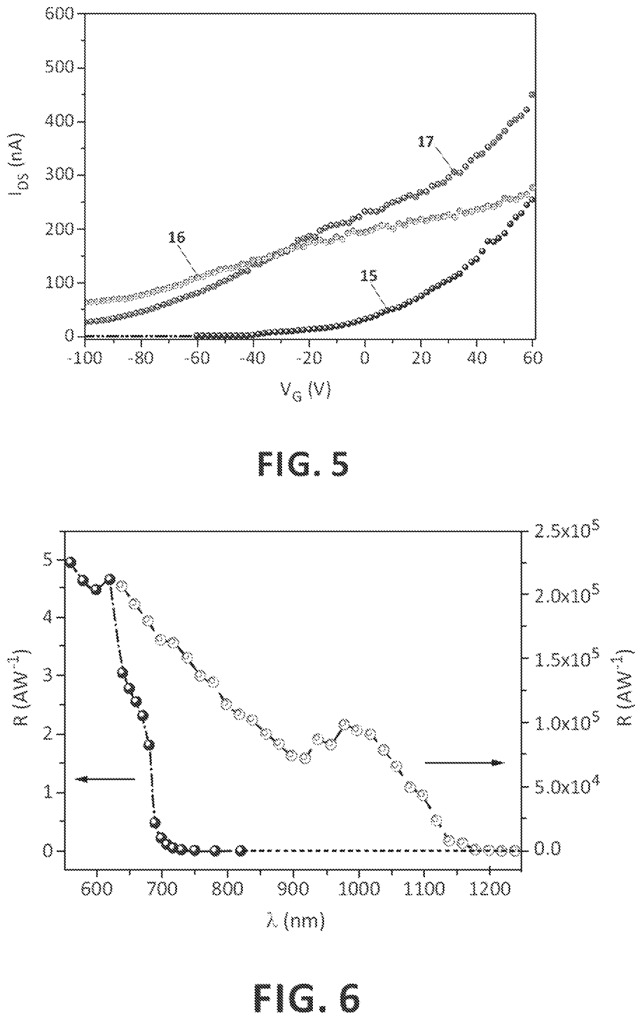

FIG. 5 displays the field effect transistor (FET) characteristics of a bilayer MoS₂ transistor 15 and its MoS₂/PbS hybrid device fabricated on a Si/SiO₂ substrate. All measurements were performed in two-probe configuration and carried out under ambient conditions. The source-drain current (I_{DS}) modulation characteristic as a function of V_{G} and under bias voltage V_{DS}=50 mV is presented in linear scale. The bilayer MoS₂ transistor 15 shows a field effect mobility of 10-20 cm²V⁻¹ s⁻¹ in the linear regime and on/off-ratios in the range of 10⁵-10⁶. A significant increase in the drain current of MoS₂/PbS transistors is observed for the MoS₂/PbS hybrid device, both for light 16 and dark 17 states. Similar results are obtained for photodetectors with a transport layer made of MoS₂, and a photosensitizing layer comprising colloidal quantum dots made of any of Ge, HgTe, and AgBiSe₂, and for photodetectors with a transport layer made of any of MoSe₂, WS₂, WSe₂, and a photosensitizing layer comprising colloidal quantum dots made of any of Ge, HgTe, AgBiSe₂, and PbS.

FIG. 6 shows the spectral responsivity of a MoS₂-only 19 phototransistor that exhibits a responsivity up to 5 A/W, being its spectral sensitivity determined by the bandgap of a 2-layer flake of around 1.8 eV. The equivalent hybrid MoS₂-Pbs 18 detector shows dramatically higher responsivity on the order of 10⁵-10⁶ A/W and its spectral sensitivity is now extended to near infrared, as dictated by the bandgap of the PbS QDs. While the MoS₂ device absorbs only until a wavelength of ˜700 nm, the hybrid follows clearly the expected PbS absorption with a exciton peak at 980 nm, which can be tuned by controlling the quantum dot species and size. This allows the development of detectors that have sensitivity further into the short-wave infrared using larger PbS QDs and/or alternative QD species. Similar results and conclusions can be made for photodetectors with a transport layer made of MoS₂, and a photosensitizing layer comprising colloidal quantum dots made of any of Ge, HgTe, and AgBiSe₂, and for photodetectors with a transport layer made of any of MoSe₂, WS₂, WSe₂, and a photosensitizing layer comprising colloidal quantum dots made of any of Ge, HgTe, AgBiSe₂, and PbS.

Experimental results therefore prove an increased responsivity under similar dark currents than graphene-based photodetectors, as well as a more extended spectral range than traditional MoS₂ devices, or traditional MoSe₂, WS2, WSe₂ devices.

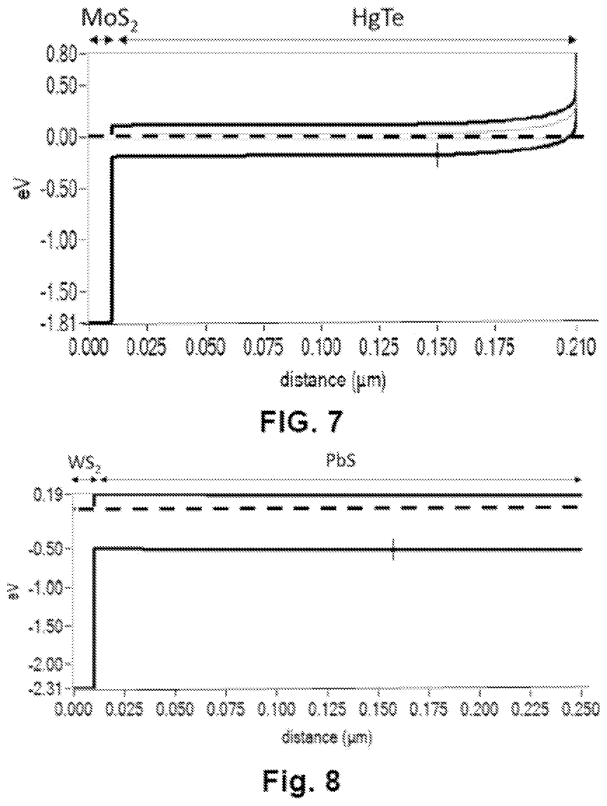

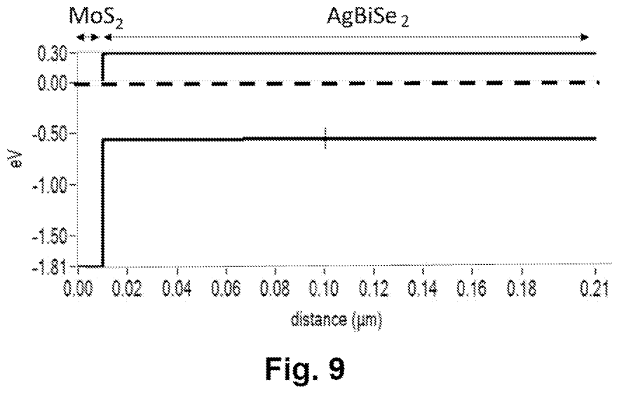

FIGS. 7-9 show simulation results obtained with the optoelectronic apparatus of the present invention, for three combinations of the above mentioned materials, showing that each of them indeed form a type II heterojunction, particularly for MoS₂/HgTe (FIG. 7), WS₂/PbS (FIG. 8), and MoS₂/AgBiSe₂ (FIG. 9).

| | MoS₂ | HgTe |
|---|---|---|
| Bandgap [eV] | 1.8 | 0.3 |
| Electron affinity | 4.3 | 4.2 |

| | WS₂ | PbS |
|---|---|---|
| Bandgap [eV] | 2.3 | 0.7 |
| Electron affinity | 4.7 | 4.5 |

| | MoS₂ | AgBiSe₂ |
|---|---|---|
| Bandgap [eV] | 1.8 | 0.85 |
| Electron affinity | 4.3 | 4 |

The simulations have been made with the apparatuses modelled with SOAPS, a 1-D simulator for thin film semiconductor devices: M. Burgelman, K. Decock, S. Khelifi and A. Abass, “Advanced electrical simulation of thin film solar cells”, Thin Solid Films, 535 (2013) 296-301.

What is claimed is:

1. An optoelectronic apparatus comprising: a substrate, a dielectric layer, a transport layer, and a photosensitizing layer, wherein:
the transport layer comprises at least one 2-dimensional semiconductor layer, wherein the material of the 2-dimensional semiconductor layer is MoS₂;
the photosensitizing layer comprises colloidal quantum dots for absorbing light that, in response to incident light, generates pairs of electric carriers, traps a single type of electric carriers of said pairs therein, and transfers a distinct single type of electric carriers of said pairs to the transport layer, to be transported thereby, wherein the material of said colloidal quantum dots is selected from the group consisting of Ge, HgTe, and AgBiSe₂; and
wherein the optoelectronic apparatus further comprises:
a first electrode and a second electrode connected to the transport layer, the transport layer being adapted to generate, and make flow through a transport channel, an electric current between the first electrode and the second electrode upon incidence of incoming light in the photosensitizing layer;
and further wherein a type-II heterojunction is formed between the photosensitizing layer and the transport layer to thereby provide a photoconductive gain.

2. The optoelectronic apparatus according to claim 1, further comprising a third electrode connected to the substrate; and a voltage source connected to the third electrode and providing a bias voltage thereto to tune a conductivity of the transport layer by applying the bias voltage to the third electrode, to the point that the transport channel is depleted of free carriers in order to minimize its conductivity in dark.

3. The optoelectronic apparatus according to claim 2, wherein said bias voltage provided by the voltage source ranges from 0.1 V to 10 V or from −0.1 to −10V.

4. The optoelectronic apparatus according to claim 1, further comprising a top electrode on top of the photosensitizing layer or on top of a dielectric layer arranged on top of the photosensitizing layer.

5. The optoelectronic apparatus according to claim 1, wherein the substrate layer comprises a doped semiconductor selected from the group consisting of Si, ITO, aluminum doped zinc oxide (AZO), and graphene.

6. The optoelectronic apparatus according to claim 1, wherein the material of the dielectric layer is selected from the group consisting of SiO₂, HfO₂, Al₂O₃, parylene, and boron nitride.

7. The optoelectronic apparatus according to claim 1, wherein the transport layer consists of a number of 2-dimensional semiconductor layers ranging from one to one hundred.

8. The optoelectronic apparatus according to claim 1, further comprising an interlayer barrier between the transport layer and the photosensitizing layer.

9. The optoelectronic apparatus according to claim 8, wherein the interlayer barrier is selected from the group consisting of ZnO, TiO₂, Alumina, Hafnia, and boron nitride.

10. The optoelectronic apparatus according to claim 8, wherein the interlayer barrier comprises a self-assembled monolayer of organic molecules selected from the group consisting of ethanedithiol, propanedithiol, butanedithiol, octanedithiol, and dodecanedithiol.

11. The optoelectronic apparatus according to claim 8, wherein the interlayer barrier has a thickness between 0.1 and 10 nm.

12. The optoelectronic apparatus according to claim 8, wherein the interlayer barrier forms a type-II heterojunction with the photosensitizing layer, and a type-II or type-I heterojunction with the transport layer.

13. An optoelectronic apparatus comprising: a substrate, a dielectric layer, a transport layer, and a photosensitizing layer, wherein:
the transport layer comprises at least one 2-dimensional semiconductor layer, wherein the material of the 2-dimensional semiconductor layer is selected from the group consisting of MoSe₂, WS₂, WSe₂, and SnS₂;
the photosensitizing layer comprises colloidal quantum dots for absorbing light that, in response to incident light, generates pairs of electric carriers, traps a single type of electric carriers of said pairs therein, and transfers a distinct single type of electric carriers of said pairs to the transport layer, to be transported thereby, wherein the material of said colloidal quantum dots is selected from the group consisting of Ge, HgTe, and AgBiSe₂; and
wherein the optoelectronic apparatus further comprises:
a first electrode and a second electrode connected to the transport layer, the transport layer being adapted to generate, and make flow through a transport channel, an electric current between the first electrode and the second electrode upon incidence of incoming light in the photosensitizing layer;
and further wherein a type-II heterojunction is formed between the photosensitizing layer and the transport layer to thereby provide a photoconductive gain.

14. The optoelectronic apparatus according to claim 13, further comprising a third electrode connected to the substrate; and a voltage source connected to the third electrode and providing a bias voltage thereto to tune a conductivity of the transport layer by applying the bias voltage to the third electrode, to the point that the transport channel is depleted of free carriers in order to minimize its conductivity in dark.

15. The optoelectronic apparatus according to claim 14, wherein said bias voltage provided by the voltage source ranges from 0.1 V to 10 V or from −0.1 to −10V.

16. An optoelectronic apparatus comprising: a substrate, a dielectric layer, a transport layer, and a photosensitizing layer, wherein:
the transport layer comprises at least one 2-dimensional semiconductor layer, wherein the material of the 2-dimensional semiconductor layer is selected from the group consisting of MoSe₂, WS₂, WSe₂, and SnS₂;
the photosensitizing layer comprises colloidal quantum dots for absorbing light that, in response to incident light, generates pairs of electric carriers, traps a single type of electric carriers of said pairs therein, and transfers a distinct single type of electric carriers of said pairs to the transport layer, to be transported thereby, wherein the material of said colloidal quantum dots is PbS; and
wherein the optoelectronic apparatus further comprises:
a first electrode and a second electrode connected to the transport layer, the transport layer being adapted to generate, and make flow through a transport channel, an electric current between the first electrode and the second electrode upon incidence of incoming light in the photosensitizing layer;
and further wherein a type-II heterojunction is formed between the photosensitizing layer and the transport layer to thereby provide a photoconductive gain.

17. The optoelectronic apparatus according to claim 16, further comprising a third electrode connected to the substrate; and a voltage source connected to the third electrode and providing a bias voltage thereto to tune a conductivity of the transport layer by applying the bias voltage to the third electrode, to the point that the transport channel is depleted of free carriers in order to minimize its conductivity in dark.

18. The optoelectronic apparatus according to claim 17, wherein said bias voltage provided by the voltage source ranges from 0.1 V to 10 V or from −0.1 to −10V.
